(19) United States
(12) Patent Application Publication
(10) Pub. No.: US 2006/0244110 A1
(43) Pub. Date: Nov. 2, 2006

(54) Electronic device

(75) Inventor: Seiji Omura, Kobe-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO ELECTRIC CO., LTD., Moriguchi-shi (JP)

(21) Appl. No.: 11/411,018

(22) Filed: Apr. 26, 2006

(30) Foreign Application Priority Data
Apr. 28, 2005 (JP) 2005-130781

(51) Int. Cl. H01L 23/495

(52) U.S. Cl. 257/668

(57) ABSTRACT

An upper connecting part of an electrode terminal connected to an upper side electrode in an electrode holding vessel of a power storage device is disposed below a lower connecting part of an electrode terminal connected to a lower side electrode in the electrode holding vessel. Additionally, the electrode holding vessel is disposed above a surface connecting the upper connecting part and the lower connecting part.

The priority application Number JP2005-130781 upon which this patent application is based are hereby incorporated by reference.

### BACKGROUND OF THE INVENTION

1. Field of the Invention

The present invention relates to an electronic device that can be soldered to a mounting substrate.

2. Description of the Prior Art

A power storage device having a coin type structure shown in FIG. 10 and FIG. 11 (JP 2004-165537 A, page 6, FIG. 1) is generally known. FIG. 10 is a plan view illustrating a conventional power storage device and FIG. 11 is a cross sectional view illustrating a conventional power storage device.

In reference to FIG. 10 and FIG. 11, a conventional power storage device 100 is comprised of an armoring cover 104, an armoring case 106, a lead terminal 111 and a lead terminal 112. The armoring case 106 internally includes two electrodes that are electrically insulated by a separator.

The armoring cover 104 is composed of conductive materials and connected to one electrode inside the armoring case 106. A bottom surface of the armoring case 106 is composed of conductive materials and connected to the other electrode inside the armoring case 106.

The lead terminal 111 is connected to an outer peripheral surface of the armoring case 106, and the lead terminal 112 is connected to the armoring cover 104.

The conventional power storage device 100 is attached to a printed circuit board for example by the lead terminals 111 and 112 to be used as backup power for memory of a digital equipment and the like.

In recent years, digital equipments have tendency to be provided with higher-performance and multiple functions as well as become reduced in size and in thickness. Accordingly, both electronic components and circuit boards built in digital equipments are also required to be provided with higher-performance and multiple functions as well as become smaller in size and thinned down.

In addition, higher-performance and multiple functions of digital equipments require many electronic components mounted on a substrate. Therefore, the following soldering technology is used in order to mount electronic components such as a power storage device on a substrate. That is, cream solder is applied to a part for attaching electronic components on the substrate, and the electronic components are mounted on the coating surface of the cream solder to be guided through a reflow oven. Then, the electronic components are heated up to high temperature of about 200 degrees Celsius inside the reflow oven for a short time to melt the solder, thereby connected to the substrate.

Additionally, electronic components and electronic materials used in electronic products are becoming Pb-free, which means they do not contain plumbum because of environmental concerns. Therefore, as to soldering materials used for joining, various kinds of Pb-free materials such as Sn—Ag based, Sn—Ag—Cu based, Sn—Cu based, Sn—Bi based and Sn—Zn based are also studied or introduced.

Sn—Pb eutectic alloy solder containing Pb has wetting and spreading rate of nearly 90% whereas Pb-free alloy solder containing Sn—Ag—Cu alloy has wetting and spreading rate of 80% or less, which has rather less wettability in comparison with soldering materials containing Pb (See page 74 of “the plumbum-free solder mounting technology”, Corona Corporation, 2003).

### SUMMARY OF THE INVENTION

In recent years, a mounting substrate is formed by laminating paper, glass fabric or synthetic fiber fabric for example impregnated with phenolic resin or epoxy resin, or by laminating such material as fluorocarbon resin, polyimide resin or polyester resin with copper foil applied to one side or both sides thereof.

In order to reduce size and thickness of a digital equipment, a component is expected to be reduced in thickness, and a mounting substrate to be used is also expected to be reduced in thickness with more layers. In order to reduce thickness of a mounting substrate with more layers, its constituent materials are thinned down and a through-hole, a via and the like are heavily used to connect an upper side circuit pattern and a lower side circuit pattern.

In a mounting substrate, a metal foil part of a copper pattern and the like that is a connecting part of an electrode terminal of a power storage device and a resin part and the like that is an insulating part except for the metal foil part have different coefficients of thermal expansion. Further, a multilayered mounting substrate reduced in thickness is liable to warp since a trough-hole, a via and the like are heavily used.

FIG. 12, FIG. 13 and FIG. 14 are respectively a first, a second and a third views illustrating problems in mounting a conventional power storage device on a substrate, and FIG. 15 and FIG. 16 are respectively a first and a second cross sectional views showing an attaching state of the power storage device to a mounting substrate. In reference to FIG. 12, FIG. 13 and FIG. 14, a power storage device 100 further comprises a gasket 105. The gasket 105 is interposed between an armoring cover 104 and an armoring case 106. And an electrode holding vessel 118 is comprised of the armoring cover 104, the gasket 105, and the armoring case 106.

In the power storage device 100, a lead terminal 111 has a connecting part 111a and a lead terminal 112 has a connecting part 112a. The connecting parts 111a and 112a are respectively disposed at the lowermost ends of the lead terminals 111 and 112 in the thickness direction of the power storage device 100. Each connecting part 111a and 112a is a connecting part for connecting the power storage device 100 to an external circuit.

When a distance L4 between the connecting part 111a and the connecting part 112a in the thickness direction of the electronic device 100 (See FIG. 12) equals to zero, the connecting part 111a and the connecting part 112a contact a mounting substrate surface 108 (See FIG. 13).

After being guided through a reflow oven that is a heating process for soldering, however, a mounting substrate 107 warps as illustrated in FIG. 14. Consequently, a distance L5 between the connecting part 111a and the connecting part 112a equals to more than zero, and thereby the connecting part 112a is positioned above the mounting substrate surface 108 (See FIG. 14). As a result, as illustrated in FIG. 15, solder 109 flows only toward the mounting substrate surface 108 without flowing toward the connecting part 112a and thereby cannot join the connecting part 112a to the mounting substrate 107.

In the future, digital equipments are expected to be reduced in size and in thickness, and accordingly the multilayered thin mounting substrate 107 which is liable to warp is expected to be heavily used. Moreover, as described above, Pb-free soldering materials are also expected to be heavily used because of environmental concerns. Accordingly, bad soldering of the power storage device 100 is liable to occur.

In addition, as illustrated in FIG. 16, when a land 110 of the mounting substrate 107 which mounts the power storage device 100 is large (the thickness of the land 110 is exaggerated in FIG. 16), there is a problem of short-circuit in the lower surface of the electrode holding vessel.

Further, when the temperature inside a reflow oven exceeds an upper temperature limit of electrolyte solution and the like used in the power storage device 100, the power storage device 100 is manually soldered. Therefore, the deformation of the connecting part 112a under pressure has to be taken into consideration.

The present invention intends to solve above-described problems and has an objective to provide an electronic device that can be precisely soldered to even an easily warping mounting substrate.

### BRIEF DESCRIPTION OF THE DRAWINGS

FIG. 1 is a first schematic cross-sectional view illustrating a power storage device according to an embodiment of the present invention.

FIG. 2 is a second schematic cross-sectional view of the power storage device according to the embodiment of the present invention.

FIG. 3 is a cross-sectional view showing an attaching state of the power storage device illustrated in FIG. 1 and FIG. 2 to a mounting substrate.

FIG. 4 is a schematic cross-sectional view of a power storage device according to another embodiment of the present invention.

FIG. 5 is a cross-sectional view showing an attaching state of the power storage device illustrated in FIG. 4 to the mounting substrate.

FIG. 6 is a schematic cross-sectional view of a power storage device according to yet another embodiment of the present invention.

FIG. 7 is a cross-sectional view showing an attaching state of the power storage device illustrated in FIG. 6 to the mounting substrate.

FIG. 8 is another cross-sectional view showing the attaching state of the power storage device illustrated in FIG. 1 to the mounting substrate.

FIG. 9 is another cross-sectional view showing the attaching state of the power storage device illustrated in FIG. 4 to the mounting substrate.

FIG. 10 is a plan view of a conventional power storage device.

FIG. 11 is a cross-sectional view of the conventional power storage device.

FIG. 12 is a first view for illustrating a problem in mounting the conventional power storage device on the substrate.

FIG. 13 is a second view for illustrating a problem in mounting the conventional power storage device on the substrate.

FIG. 14 is a third view for illustrating a problem in mounting the conventional power storage device on the substrate.

FIG. 15 is a first cross-sectional view showing an attaching state of the conventional power storage device to a mounting substrate.

FIG. 16 is a second cross sectional view showing an attaching state of the conventional power storage device to the mounting substrate.

### DETAILED DESCRIPTION OF THE PREFERRED EMBODIMENTS

Embodiments of the present invention will be described in detail with reference to the drawings. The same reference numbers are given to components which are identical with or equivalent to each other, and their descriptions will be omitted to avoid repetition.

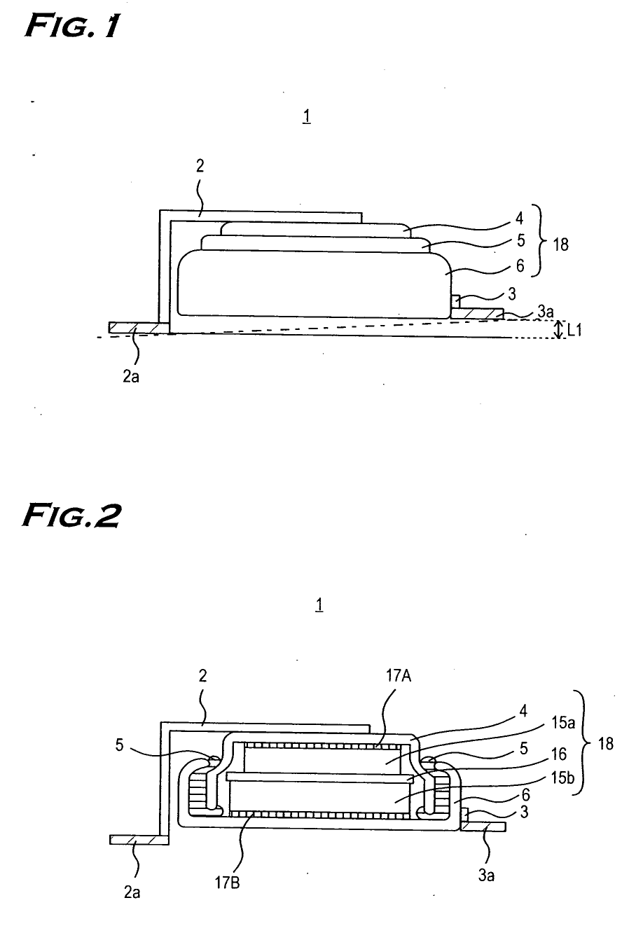

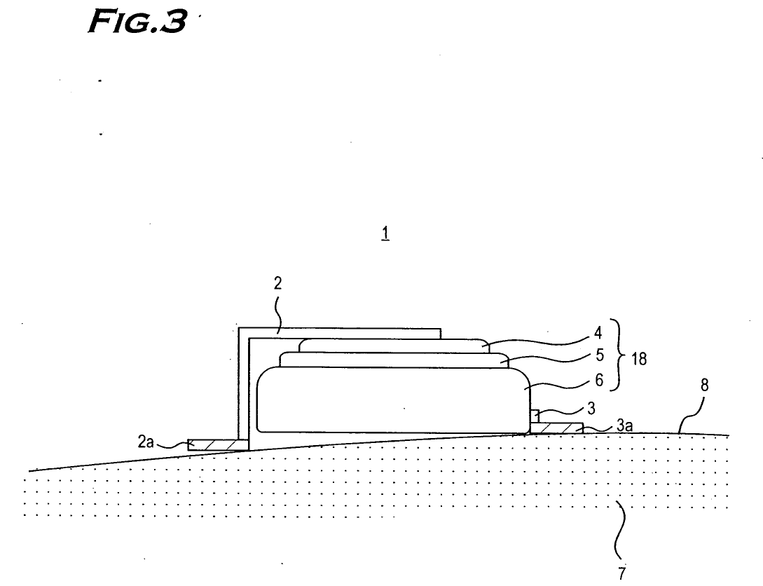

FIG. 1 and FIG. 2 are respectively a first and a second schematic cross-sectional view illustrating a power storage device according to an embodiment of the present invention. In reference to FIG. 1, a power storage device 1 according to the embodiment of the present invention comprises an electrode terminal 2, an electrode terminal 3, an armoring cover 4, a gasket 5, an armoring case 6, an electrode 15a, an electrode 15b and a separator 16.

The armoring cover 4 and the armoring case 6 are respectively composed of such conductive material as stainless steel for example. The electrode 15a and the electrode 15b are respectively composed of materials used for secondary battery such as activated carbon using coconut shells, activated carbon fiber using phenolic resin, expansive carbonaceous materials, activated carbonaceous materials mixed with fine particles, materials forming conductive polymers on a surface of activated carbon, cobalt based lithium composite metal oxide and nickel-based lithium composite metal oxide for example.

As electrolyte solution, generally known strong acid water solution, strong alkaline water solution, nonaqueous solution dissolving strong acid alkali metal salt in aprotic organic solvent or nonaqueous solution dissolving quaternary salt in aprotic organic solvent or the like is used. And the electrode 15a, the electrode 15b and the separator 16 are impregnated with electrolyte solution. In the result, ions in electrolyte solution are adsorbed on and desorbed from the electrode 15a and the electrode 15b, and consequently the power storage device 1 implements charging and discharging.

The electrode 15a, the electrode 15b and the separator 16 are stored inside the armoring case 6. A part of the armoring cover 4 is disposed inside the armoring case 6 in order to cover the electrode 15a, the electrode 15b and the separator 16.

The electrodes 15a and 15b are electrically insulated by the separator 16. The electrode 15a is electrically connected to the armoring case 4 by a conductive adhesive 17A and the electrode 15b is electrically connected to the armoring case 6 by a conductive adhesive 17B. Accordingly, the electrode 15a, the electrode 15b and the separator 16 are sandwiched between the armoring cover 4 and the armoring case 6.

A gasket 5 inside the armoring case 6 is interposed between the armoring cover 4 and the armoring case 6, thereby electrically insulating the armoring cover 4 from the armoring case 6.

An electrode terminal 2 is connected to the armoring cover 4 at one end having a connecting part 2a at the other end. And an electrode terminal 3 is connected to an outer peripheral surface of the armoring case 6 at one end having a connecting part 3a at the other end. The connecting part 2a of the electrode terminal 2 is provided at the lowermost part of the electrode terminal 2 in the thickness direction of the power storage device 1, and the connecting part 3a of the electrode terminal 3 is provided at the lowermost part of the electrode terminal 3 in the thickness direction of the power storage device 1.

The connecting part 2a of the electrode terminal 2 is disposed below the connecting part 3a of the electrode terminal 3 in the thickness direction of the power storage device 1. A distance L1 between the connecting part 2a and the connecting part 3a is set greater than zero.

In the power storage device 1, an electrode holding vessel 18 comprises the armoring cover 4, the gasket 5 and the armoring case 6 and is disposed above a plane connecting the connecting part 2a and the connecting part 3a.

A manufacturing method of the power storage device 1 illustrated in FIG. 1 and FIG. 2 will be described. Material mixed with coconut shell activated carbon, carbon black and binder bond and so on is spread thinly in the same thickness as the electrodes 15a and 15b to make electrode material. After that, the electrode material is punched out, thereby manufacturing the electrodes 15a and 15b to be used for electric double layers.

Afterwards, the conductive adhesive 17A is applied to the armoring cover 4 made of stainless steel, and the electrode 15a is attached to the armoring cover 4 thereby impregnating the electrode 15a with electrolyte solution. Further, the conductive adhesive 17B is applied to the armoring case 6, and the electrode 15b is attached to the armoring case 6, thereby impregnating the electrode 15b with electrolyte solution. After that, the separator 16 is placed on the electrode 15b to impregnate the separator 16 with electrolyte solution. The insulating gasket 5 is attached to the inner periphery of the armoring case 6, and the armoring cover 4, the gasket 5 and the armoring case 6 seal the electrode 15a, the electrode 15b and the separator 16, thereby manufacturing the electrode holding vessel 18.

Subsequently, the electrode terminal 2 and the electrode terminal 3 are connected to the armoring cover 4 and the armoring case 6 respectively by laser welding. Here, the electrode terminal 2 and the electrode terminal 3 are respectively connected to the armoring cover 4 and the armoring case 6 so that the distance L1 between the connecting part 2a of the electrode terminal 2 and the connecting part 3a of the electrode terminal 3 is greater than zero, thereby completing the power storage device 1.

FIG. 3 is a cross-sectional view showing an attaching state of the power storage device 1 illustrated in FIG. 1 and FIG. 2 to a mounting substrate. As illustrated in FIG. 3, a mounting substrate 7 convexly warps. The connecting part 2a and the connecting part 3a are connected to a surface 8 of the mounting substrate 7 and thereby the power storage device 1 is mounted on the warping mounting substrate 7. In this case, the distance L1 between the connecting part 2a and the connecting part 3a is greater than zero, and therefore both the connecting part 2a and the connecting part 3a contact the convexly warping mounting substrate 7.

Even when the mounting substrate 7 does not warp, both the connecting part 2a and the connecting part 3a contact the unwarping mounting substrate 7 because the electrode terminal 2 is elastic.

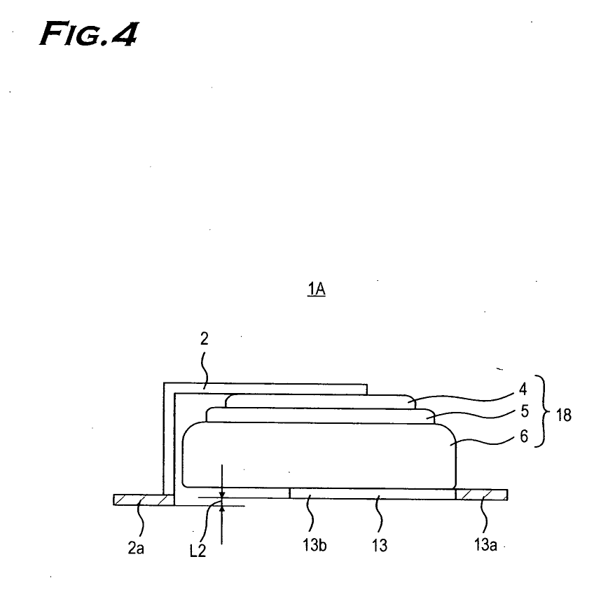

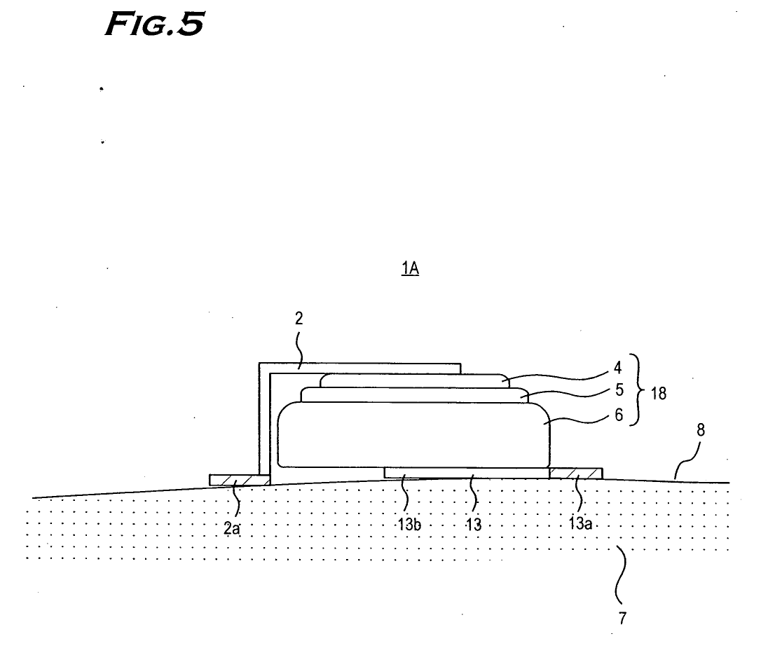

FIG. 4 is a schematic cross-sectional view of a power storage device according to another embodiment of the present invention. With reference to FIG. 4, a power storage device 1A is the same as the power storage device 1 except the electrode terminal 3 of the power storage device 1 illustrated in FIG. 1 and FIG. 2 replaced by an electrode terminal 13.

The electrode terminal 13 is in a nearly flat plate shape and has a connecting part 13a and a connecting part 13b. And the connecting part 13b is connected to the bottom surface of the armoring case 6. In the power storage device 1A, a distance L2 between the connecting part 2a and the connecting part 13a in the thickness direction of the power storage device 1A is set greater than zero.

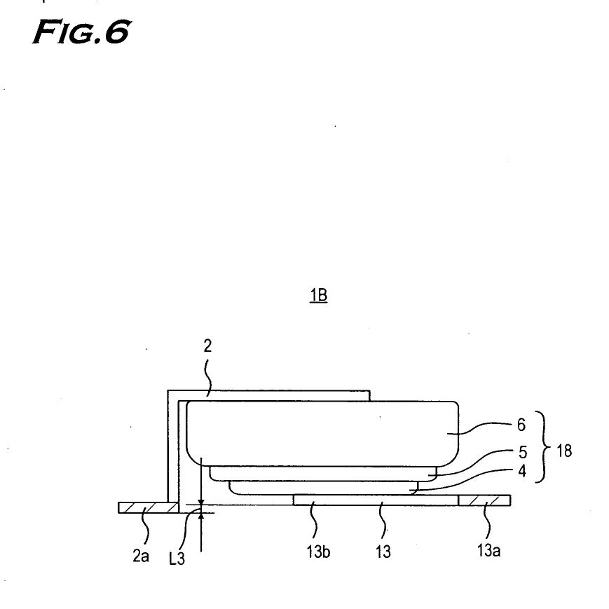

FIG. 5 is a cross-sectional view showing an attaching state of the power storage device 1A illustrated in FIG. 4 to the mounting substrate. In reference to FIG. 5, the connecting part 2a and the connecting part 13a are connected to the surface 8 of the mounting substrate 7 and thereby the power storage device 1A is mounted on the convexly warping mounting substrate 7. In this case, the distance L2 between the connecting part 2a and the connecting part 13a is greater than zero, and therefore both the connecting part 2a and the connecting part 13a contact the convexly warping mounting substrate 7.

Even when the mounting substrate 7 does not warp, both the connecting part 2a and the connecting part 3a contact the unwarping mounting substrate 7 because the electrode terminal 2 is elastic.

FIG. 6 is a schematic cross-sectional view of a power storage device according to yet another embodiment of the present invention. With reference to FIG. 6, a power storage device 1B interchanges the electrode terminal 2 and the electrode terminal 13 in the power storage device 1A illustrated in FIG. 4 and is the same as the power storage device 1A in other aspects. Accordingly, in the power storage device 1B, the electrode terminal 2 is connected to the armoring case 6 and the electrode terminal 13 is connected to the armoring cover 4. And a distance L3 between the connecting part 2a of the electrode terminal 2 and the connecting part 13a of the electrode terminal 13 in the thickness direction of the power storage device 1B is set greater than zero.

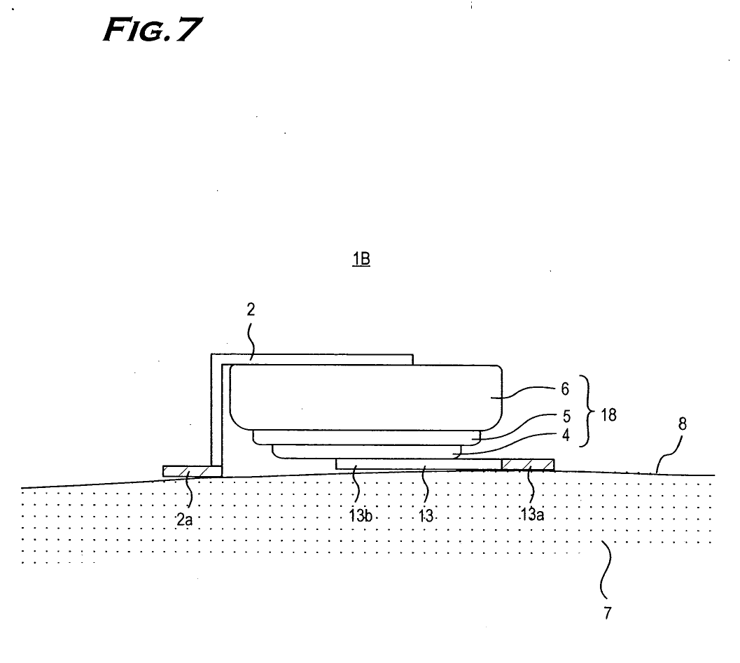

FIG. 7 is a cross-sectional view showing an attaching state of the power storage device 1B illustrated in FIG. 6 to a mounting substrate. As illustrated in FIG. 7, the connecting part 2a and the connecting part 13a are connected to the surface 8 of the mounting substrate 7 and thereby the power storage device 1B is mounted on the convexly warping mounting substrate 7. In this case, the distance L3 between the connecting part 2a and the connecting part 13a is grater than zero, and therefore both the connecting part 2a and the connecting part 13a contact the convexly warping mounting substrate 7.

Even when the mounting substrate 7 does not warp, both the connecting part 2a and the connecting part 13a contact the unwarping mounting substrate 7 because the electrode terminal 2 is elastic.

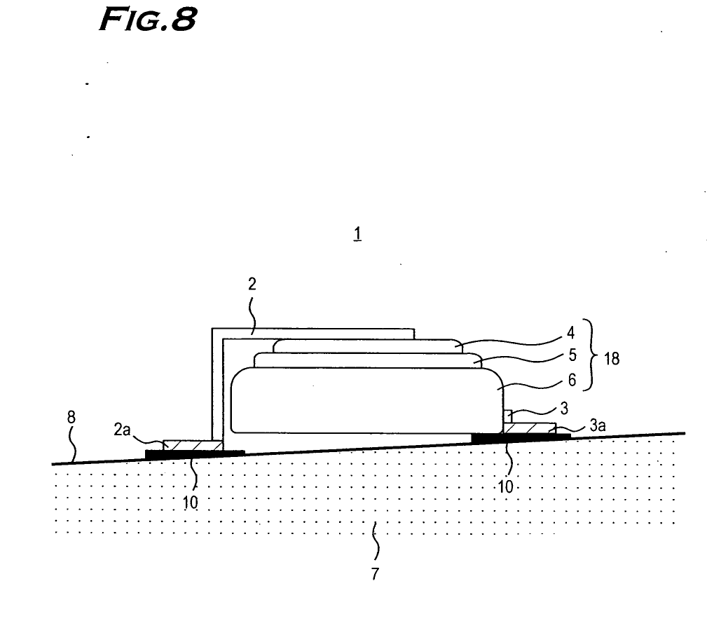

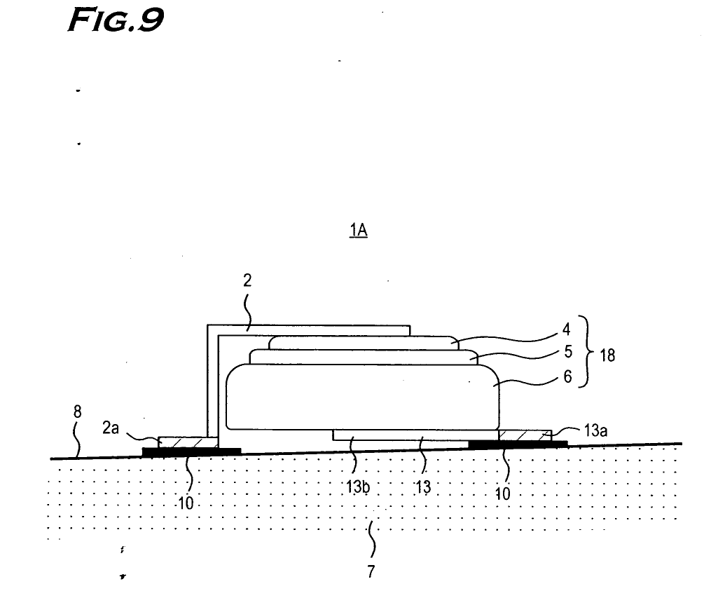

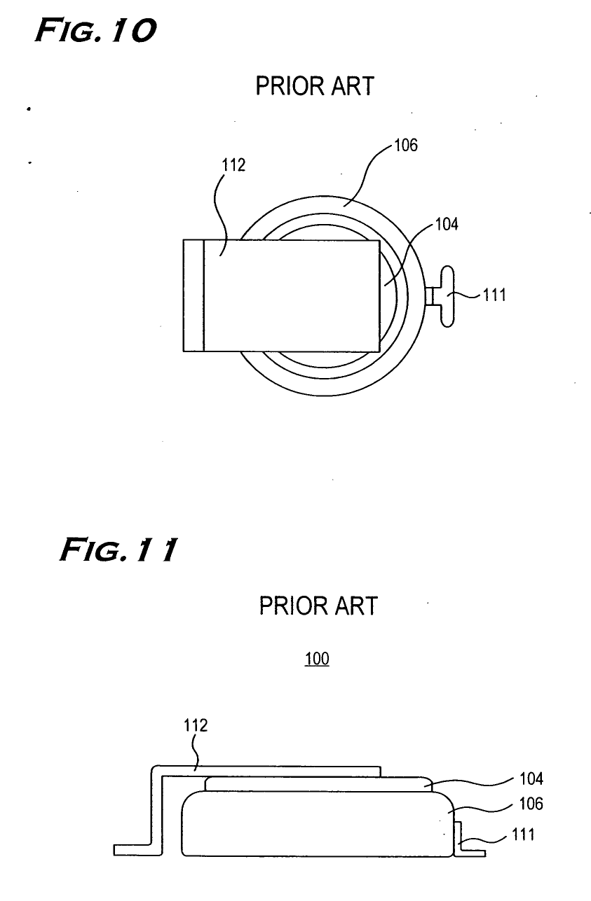

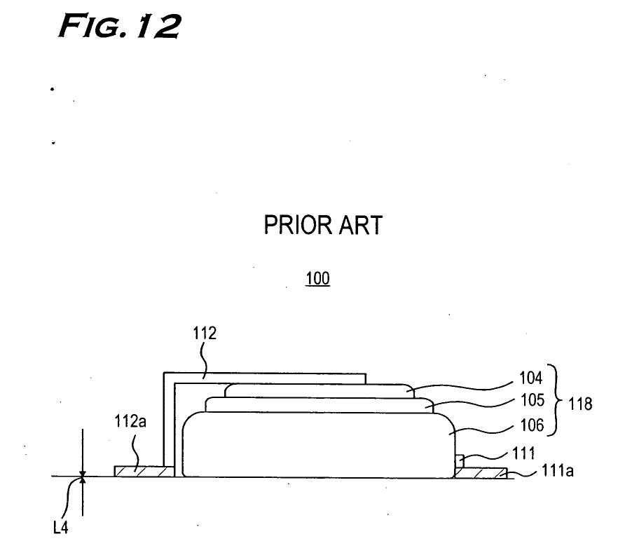

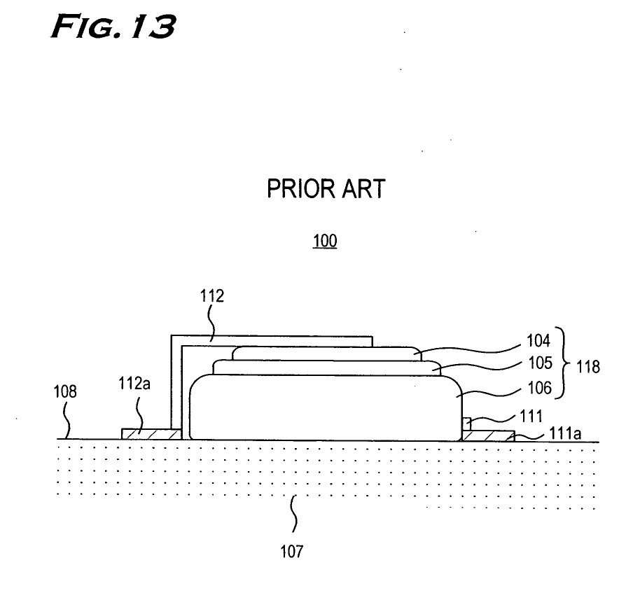

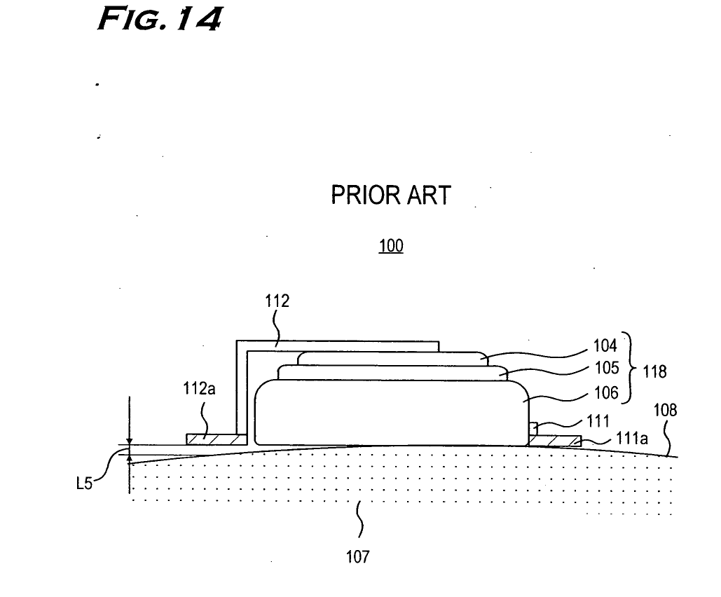

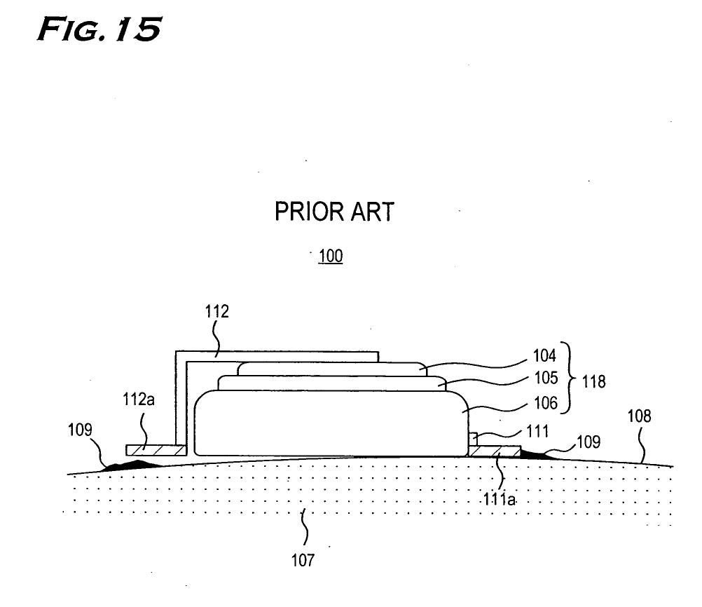

FIG. 8 is another cross-sectional view showing an attaching state of the power storage device 1 illustrated in FIG. 1 to the mounting substrate, and FIG. 9 is another cross-sectional view showing an attaching state of the power storage device 1A illustrated in FIG. 4 to the mounting substrate.

As described above, the electrode holding vessel 18 is disposed above a plane connecting the connecting part 2a of the electrode terminal 2 and the connecting part 3a of the electrode terminal 3. Therefore, even when a land 10 of the mounting substrate 7 is large and the power storage device 1 is misaligned when soldered, short circuit between the bottom surface of the electrode holding vessel 18 and the connecting part 2a does not occur, thereby not destroying the power storage device 1 (See FIG. 8). In the power storage device 1, the connecting part 3a connected to the bottom surface of the electrode holding vessel 18 is not needed because the connecting part 3a of the electrode terminal 3 is connected to the side surface of the armoring case 6. As a result, the power storage device 1 is reduced in its whole thickness to be suitable for components of thin-outline digital equipments.

In the power storage device 1A, the connecting part 13a of the electrode terminal 13 is connected to the bottom surface of the electrode holding vessel 18, and therefore a space between the surface 8 of the mounting substrate 7 and the electrode holding vessel 18 becomes wide. Consequently, when the power storage device 1A is manually soldered, the bottom surface of the electrode holding vessel 18 can be further prevented from contacting the land 10 of the mounting substrate 7 even under pressure (See FIG. 9).

A solder joining test of the aforementioned power storage devices 1, 1A and 1B to a mounting substrate will be described. For comparison, a power storage device 100 illustrated in FIG. 12 is used. In other words, the power storage device 100 in which a distance L4 between the connecting part 111a of the lead terminal 111 and the connecting part 112a of the lead terminal 112 equals to zero in the thickness direction thereof is used as a comparative example 1. As the mounting substrate 7, an easily warping substrate impregnating paper base material with phenolic resin and to which copper foil is applied to be laminated and a hardly warping substrate impregnating glass fabric with epoxy resin and to which copper foil is applied to be laminated are prepared. Cream solder is applied to the prepared mounting substrate 7, and then electric double layers are mounted on the substrate to be guided through a reflow oven whose maximum temperature is set to 260 degrees Celsius.

Table 1 shows results of an acceptance number of solder joining to the mounting substrate 7 after the power storage devices 1, 1A, 1B of the present invention and the comparative example 1 are guided through the reflow oven.

TABLE 1

| | substrate made of a | substrate made of glass |
|---|---|---|
| | paper base impregnated | fabric impregnated |
| | with phenolic resin | with epoxy resin |
| present invention | 5/5 | 5/5 |
| comparative example | 2/5 | 4/5 |

From the results shown in Table 1, regarding the power storage devices 1, 1A and 1B of the present invention, all of 5 solder joints to both substrates passed the acceptance criteria. On the other hand, in the comparative example 1, only 2 of 5 solder joints to the substrate impregnating easily warping paper base material with phenolic resin passed the acceptance criteria and even to the substrate impregnating hardly warping glass fabric base material with epoxy rein, only 4 of 5 solder joints passed the acceptance criteria. Following reasons can be considered to explain the above results.

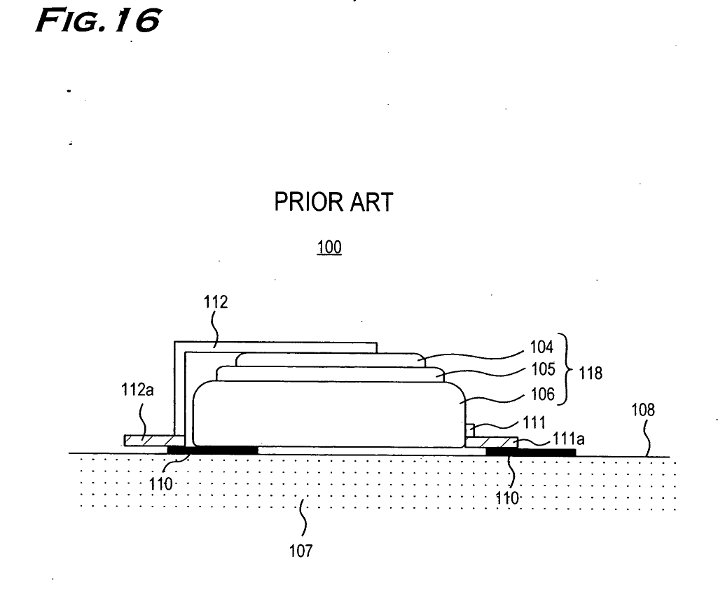

Regarding the comparative example 1, as illustrated in FIG. 15, when the connecting part 111a is disposed on the convex surface of a mounting substrate 107, a mounting substrate surface 108 is disposed below the connecting part 111a at the position of the connecting part 112a. As a result, the connecting part 112a is positioned above the mounting substrate surface 108, thereby causing solder joint failure.

Next, regarding a difference between the mounting substrates, bending strength of the substrate impregnating paper base material with phenolic resin and bending strength of the substrate impregnating glass fabric base material with epoxy rein are approximately 190 N/mm² and approximately 500 N/mm² respectively, which means that the substrate impregnating glass fabric base material with epoxy resin is 2.6 times stronger in bending strength than the substrate impregnating paper base material with phenolic resin. Accordingly, the substrate impregnating glass fabric base material with epoxy resin is hard to warp, the distance between the connecting part 112a and the mounting substrate108 becomes short. Consequently, it follows that the acceptance number of solder joining becomes larger than that of the substrate impregnating paper base material with phenolic resin.

Additionally, in the power storage device 1, 1A and 1B of the present invention, when the connecting part 3a of the electrode terminal 3 is disposed on the convex surface of the mounting substrate 7, the surface 8 of the mounting substrate 7 connected to the connecting part 2a of the electrode terminal 2 is disposed below the connecting part 3a. Nevertheless, because the connecting part 2a is disposed below the connecting part 3a, it follows that the connecting part 2a contacts the surface 8 of the mounting substrate 7 without fail, thereby leading to the large acceptance number of solder joining.

Thus, by applying the present invention, precise solder joining is achieved in both cases when the mounting substrate 7 is hard to warp and is easy to warp, thereby eliminating bad soldering.

In the above descriptions, the distances L1, L2 and L3 between the connecting part 2a of the electrode terminal 2 and the connecting part 3a of the electrode terminal 3 in the power storage device are set to a positive number. The present invention, however, is by no means limited to a power storage device only. The present invention is applicable to other devices, generally to an electronic device for example, by setting distances L1, L2 and L3 between the connecting part 2a of the electrode terminal 2 and the connecting part 3a of the electrode terminal 3 to a positive number.

It should be understood that the embodiments disclosed herein are to be taken as examples and not limited in any points. The scope of the present invention is defined not by the above described embodiments but by the following claims. All changes that fall within means and bounds of the claims, or equivalence of such means and bounds are intended to embraced by the claims.

What we claim is:

1. An electronic device comprising:
an electrode holding vessel including a first electrode and a second electrode;
a first electrode terminal having a first connecting part connected to the first electrode in the electrode holding vessel and having a second connecting part connected to a substrate; and
a second electrode terminal having a third connecting part connected to the second electrode in the electrode holding vessel and having a fourth connecting part connected to the substrate, wherein
a first distance between the first connecting part and the second connecting part in an approximately perpendicular direction to the substrate is different from a second distance between the third connecting part and the fourth connecting part in the approximately perpendicular direction, and
the electrode holding vessel is disposed above a surface connecting the second connecting part and the fourth connecting part.

2. The electronic device according to claim 1, wherein the first distance is longer than the second distance.

3. The electronic device according to claim 2, wherein the electrode holding vessel further includes a separator electrically cutting off the first electrode from the second electrode.

4. The electronic device according to claim 3, wherein the electrode holding vessel includes a conductive armoring case, a conductive armoring cover and an insulator electrically insulating the armoring case and the armoring cover.

5. The electronic device according to claim 4, wherein the armoring case is used as the second electrode terminal.

6. The electronic device according to claim 1, wherein the second electrode terminal is connected to a lower surface of the electrode holding vessel.

7. The electronic device according to claim 1, wherein the second electrode terminal is connected to a side surface of the electrode holding vessel.
